(19) United States
(12) Patent Application Publication
(10) Pub. No.: US 2019/0132916 A1
(43) Pub. Date: May 2, 2019

(54) LED LIGHT SOURCE MODULE AND MANUFACTURING METHOD

(71) Applicants: Wanjiong Lin, Ningbo (CN); Self Electronics Co., Ltd., Ningbo (CN); Self electronics USA Corporation, Norcross, GA (US)

(72) Inventors: Xiaoyun Liu, NINGBO (CN); Jianguo Dong, NINGBO (CN); Wenzhan Zhao, NINGBO (CN); Tonghua Huang, NINGBO (CN); Lihong Tong, NINGBO (CN)

(73) Assignees: Wanjiong Lin; Self Electronics Co., Ltd.; Self Electronics USA Corp.

(21) Appl. No.: 16/151,646

(22) Filed: Oct. 4, 2018

(30) Foreign Application Priority Data
Oct. 30, 2017 (CN) 201711041838.5

(51) Int. Cl. H05B 33/08; H01L 33/24; H01L 23/00; H01L 23/49

(52) U.S. Cl. CPC H05B 33/0806; H01L 23/49; H01L 24/26; H01L 33/24

(57) ABSTRACT

An LED light source module comprises a double-sided circuit board and two rivets electrically connected to both sides of the double-sided circuit board. The rivet includes a nail head, a shank, and a transition section connecting the nail head and the shank. The length of the nail head in a section along the thickness direction of the circuit substrate is greater than the width of the shank, and the transition section is a trapezoid. The short side of the trapezoid is connected to the shank, and the length of the long side of the trapezoid is smaller than the length of the nail head. The nail head is connected to the first wiring layout, and the shank is electrically connected to the second wire pattern by soldering tin. The first and second wiring layouts are electrically connected by the rivet, and the copper plating process with more serious pollution is not used, thereby reducing the cost of pollution control, and the circuit substrate of the lower-level material can be used, and further the competitiveness of the lamp having the LED light source module can be improved.

### CROSS-REFERENCE TO A RELATED APPLICATION

This application claims priority to a Chinese Patent Application No. CN 201711041838.5, filed on Oct. 30, 2017.

### FIELD OF THE TECHNOLOGY

The present invention relates to lighting system, with particular emphasis on an LED light source module and manufacturing method capable of providing specific illumination effect.

### BACKGROUND

In general daily life, various lighting devices can be seen everywhere, such as fluorescent lamps, street lamps, table lamps, art lamps, and the like. In the above lighting apparatus, a tungsten filament bulb is conventionally used as a light source. In recent years, due to the rapid development of technology, light-emitting diodes (LEDs) have been used as sources of illumination. In addition, in addition to lighting equipment, for general traffic signs, billboards, lights, etc., also use LEDs as a light source. As mentioned above, the use of light-emitting diodes as light-emitting sources has the advantages of power saving and greater brightness, so it has gradually become common in use.

With the development of lighting technology, people are increasingly demanding light sources, especially for strip lamps. The strip light is made by setting the electrical connection of several LED chips on a strip circuit board. However, in order to improve the applicability of the power supply, for example, the output of the power supply is 36 volts, but the rated voltage of the strip lamp is 12 volts, or 24 volts, etc., at this time, the strip lamp needs to be provided with some electronic components to rotate the input voltage of 36 volts to 12 or 24 volts, and the electronic components and the LED chips are electrically connected to the two sides of the circuit board, that is, the double panel. The connection method of the double-sided circuit board generally uses a copper sinking process, that is, Open a through-hole between the two sides of the circuit board, and then copper as a wire is deposited in the through-hole, thereby the electronic components on both sides of the circuit board are electrically connected.

Then, as the requirements of environmental protection become more and more strict, the heavily-polluted process of the copper-plating process makes the manufactured circuit board expensive, and because the temperature required in the copper sinking process is high, The circuit board suitable for the copper sinking process requires at least a relatively expensive substrate such as a fiberglass cloth, and is not a cheaper substrate such as a composite board. This also makes the price of existing double panels higher, which is not conducive to cost reduction and product competitiveness.

### SUMMARY OF THE INVENTION

Therefore, the present invention provides an LED light source module and manufacturing method capable of providing specific illumination effect to solve the above problem.

An LED light source module comprises a double-sided circuit board and at least one rivet electrically connected to two sides of the double-sided circuit board. The double-sided circuit board comprises a circuit substrate and at least one first wiring layout disposed on one side of the circuit substrate, and at least one second wiring layout disposed on the other side of the circuit board, and a perforation formed between the first wiring layout and the second wiring layout. The rivet is disposed in the perforation to electrically connect the first and second wiring layouts. The rivet comprises a nail head, a shank, and a transition section connecting the nail head and the shank. The length of the nail head in the cross section along the thickness direction of the circuit substrate is greater than the width of the shank, and the transition section is a trapezoid, the short side of the trapezoid is connected to the shank, the length of the long side of the trapezoid is smaller than the length of the nail head. The nail head is electrically connected to the first wiring layout, and the shank is electrically connected to the second wiring layout by soldering.

Advantageously, the circuit substrate is made of a composite board which is composited from paper material and fiber material.

Advantageously, the length of the shank is greater than the thickness of the circuit substrate.

Advantageously, the width of the shank is smaller than the diameter of the perforation.

Advantageously, the free end of the shank is tapered.

Advantageously, the rivet is made of metal.

Advantageously, the LED light source module further includes a plurality of LED chips electrically connected to one side of the double-sided circuit board, and a plurality of electronic components electrically connected to the other side of the double-sided circuit board, the LED chips is electrically connected to the first wiring layout, and the electronic component is electrically connected to the second wiring layout.

A LED light source module manufacturing method, which comprises the following steps:

providing a double-sided circuit board of the LED light source module as described in claims 1 to 7;

providing a patch machine, the patch machine including at least one nozzle mounting device, at least one suction nozzle mounted on the nozzle mounting device, and a circuit board placing table, the suction nozzle including a hollow cylinder, and a step portion disposed on the free end of the hollow cylinder, on a section along the axis of the hollow cylinder, the length of the step portion is equivalent to the length of the nail head;

providing electronic components, rivets, and LED chips to be soldered to the double-sided circuit board, and solder paste used for soldering the electronic components, rivets, LED chips, and first and second wiring layouts;

placing the double-sided circuit board on the circuit board placing table;

the patch machine is used to lay the solder paste on the side of the double-sided circuit board on which the second wiring layout is disposed and attach the electronic component;

performing reflow soldering to electrically connect the electronic component to the second wiring layout;

laying the solder paste on the side of the double-sided circuit board on which the first wiring layout is disposed by the patch machine, and attaching the LED chip while sucking the rivet through the suction nozzle, and inserting the rivet into the perforation;

performing reflow soldering to electrically connect the LED chip to the first wiring layout, and electrically connecting and fixing the nail head of the rivet to the first wiring layout;

repair welding the shank of the rivet protruding from the side of the second wiring layout to electrically connect the rivet and the second wiring layout to complete the assembly of the LED light source module.

Advantageously, the repair welding is done by hand.

Advantageously, the height of the step portion in the axial direction of the hollow cylinder is equal to the height of the nail head.

Compared with the prior art, the double-sided circuit board of the LED light source module of the present invention is electrically connected to the first and second wiring layouts and through the rivet, and does not use the heavily contaminated copper sink. The process can reduce the cost of pollution control, and at the same time, when assembling the rivet, the high temperature like the copper sink process is not required, so that the circuit substrate of a lower-grade material, such as a composite substrate containing a paper base, can be used. Therefore, the cost can be reduced in terms of materials, and the overall cost of the LED light source module can be reduced to improve the competitiveness of the lamp having the LED light source module.

### DETAILED DESCRIPTION OF THE DRAWINGS

The drawings described herein are intended to promote a further understanding of the present invention, as follows:

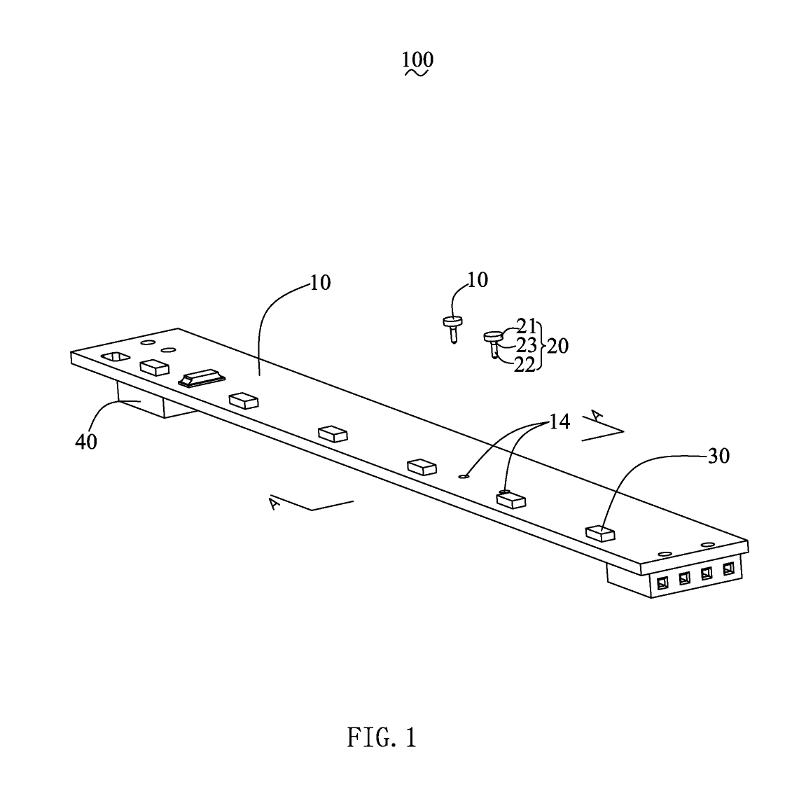

FIG. 1 is a schematic structural view of an LED light source module according to the present invention.

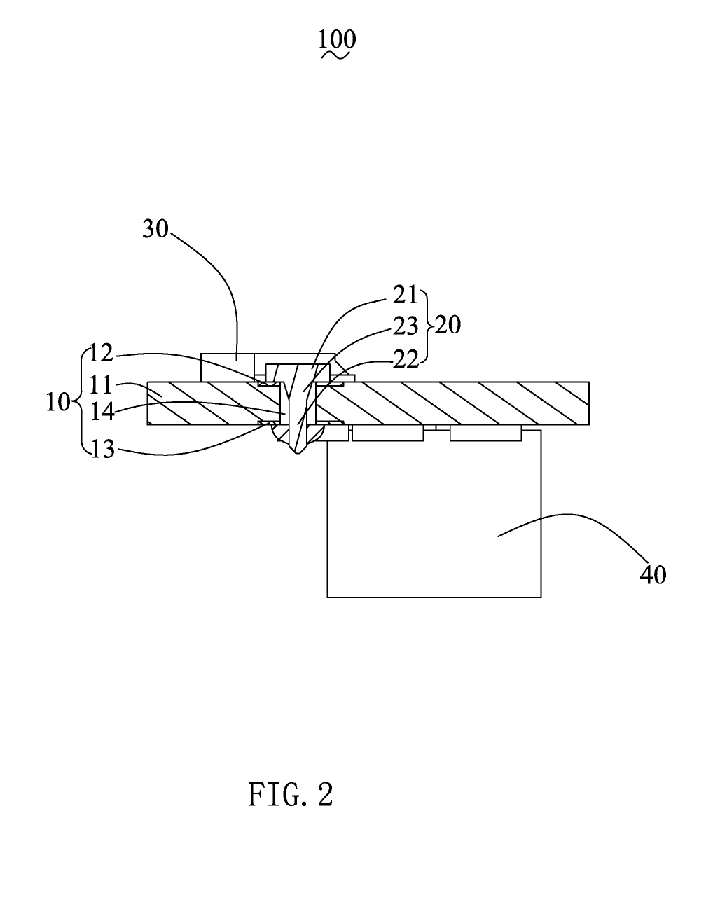

FIG. 2 is a cross-sectional structural view taken along line A-A of the LED light source module of FIG. 1.

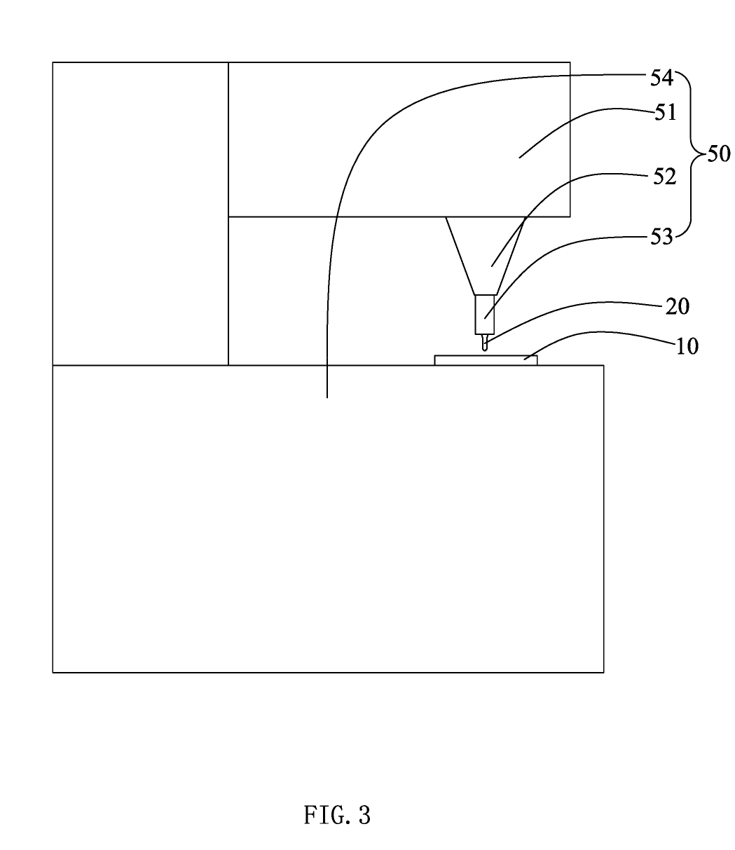

FIG. 3 is a schematic structural view of the assembly using a placement machine of the LED light source module of FIG. 1.

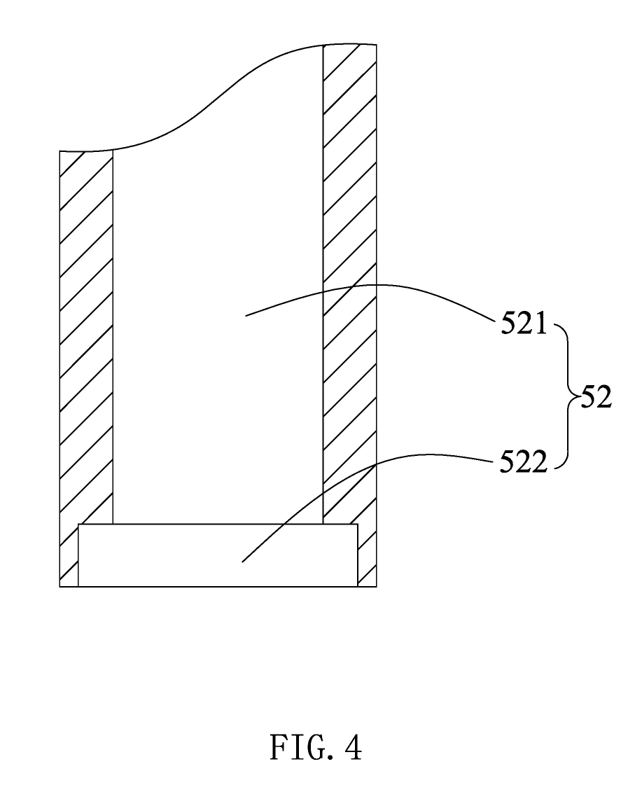

FIG. 4 is a schematic cross-sectional structural view of a suction nozzle used in the placement machine.

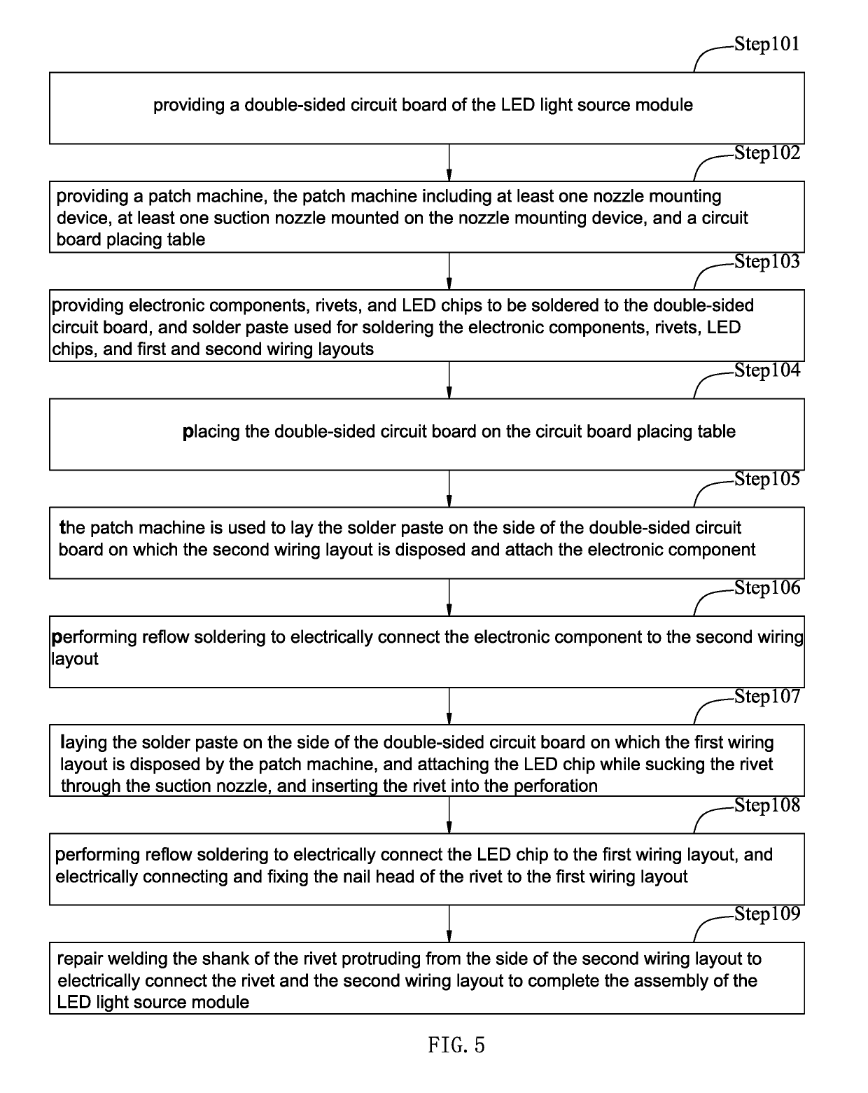

FIG. 5 is a flow chart showing the manufacture of the LED light source module of FIG. 1.

### DESCRIPTION OF THE PREFERRED EMBODIMENTS

The present application is illustrated by way of the following detailed description based on of the accompanying drawings. It should be noted that illustration to the embodiment in this application is not intended to limit the invention.

Please refer to FIG. 1 to FIG. 2, which are schematic structural diagrams of an LED light source module 100 according to the present invention. The LED light source module 100 includes a double-sided circuit board 10 and at least one rivet 20 electrically connected to two sides of the double-sided circuit board 10, and a plurality of LED chips 30 are electrically connected to one side of the double-sided circuit board 10, and a plurality of electronic components 40 electrically connected to the other side of the double-sided circuit board 10 are provided. It is conceivable that the LED light source module 100 further includes other functional modules, such as a plug-in assembly, a series-connected component, etc., which are well known to those skilled in the art and will not be described in detail herein.

The double-sided circuit board 10 includes a circuit substrate 11, at least one first wiring layout 12 disposed on one side of the circuit substrate 11, and at least one second wiring layout disposed on the other side of the circuit substrate 11. And a perforation 14 formed between the first wiring layout 12 and the second wiring layout 13. The circuit substrate 11 may be made of a composite board which may be composited from paper material and fiber material, such as a series of epoxy glass cloth paper sheets. The fibrous material may be a glass cloth, as well as synthetic fibers or the like. Of course, the circuit substrate 11 can also be a higher-grade glass cloth substrate that is not doped with paper, or the like. The first wiring layout 12 has the same structure and working principle as the second wiring layout 13, and only the first wire layout 12 is taken as an example. First, a layer of copper is arranged on the circuit substrate 11 through the rolling copper foil process or electrolytic copper foil process, then, the desired circuit connection line is formed by etching the process, and finally an insulating layer is coated on the surface of the circuit substrate provided with the copper foil, and the position where the electronic component needs to be disposed is exposed, so that the subsequent process will be electronic components are disposed on the first wiring layout 12 for electrical connection purposes. The first and second wiring layouts 12 and 13 may have the same layout design or different layout designs. In this embodiment, the first and second wiring layouts 12 and 13 have different layout designs to electrically connect different electronic components. It can be understood that the first and second wiring layouts 12 and 13 may have one or a plurality of strips as needed. In the embodiment, the double-sided circuit board 10 is provided with two first wiring layouts 12 and two second wiring layouts 13 on both sides of the circuit substrate 11 to form positive and negative circuits. The perforation 14 is defined between the first and second wiring layouts 12 and 13, that is, the perforation 14 sequentially passes through the first wiring layout 12, the circuit substrate 11, and the second wiring layout 13. It is conceivable that the perforations 14 cannot be opened in a position without the first and second wiring layouts 12, 13. The position of the perforation 14 can be set according to actual needs. Specifically, in the embodiment, the perforation 14 is disposed at the free ends of the first and second wiring layouts 12 and 13. The number of the perforations 14 is determined by the number of the first and second wiring layouts 12, 13. In the present embodiment, since the first and second wiring layouts 12 and 13 are each two, the perforations 14 also have two.

The rivet 20 includes a nail head 21, a shank 22, and a transition section 23 connecting the nail head 21 and the shank 22. The structural size of the rivet 20 is very important, so its structural size not only affects the reliability of the electrical connection, but also affects the reliability and automation performance of the production process. Since the rivet 20 acts as an electrical connection, the rivet 20 should be made of metal. In the present embodiment, the rivet 20 is made of copper. The length of the nail head 21 in the cross section along the thickness direction of the circuit substrate 11 is larger than the width of the shank 22, and the transition section 23 is a trapezoidal shape. The short side of the trapezoid is connected to the shank 22. The length of the long side of the trapezoid is smaller than the length of the nail head 21. The nail head 21 is electrically connected to the first wiring layout 12, and the shank 22 is electrically connected to the second wiring layout 13 by soldering. In order to weld the shank 22 and the second wiring layout 13 by soldering tin, the length of the shank 22 is greater than the thickness of the circuit substrate 11. The nail head 21 is circular in this embodiment in a section perpendicular to the thickness direction of the circuit substrate 11. It is conceivable that the shape of the nail head may also be other shapes such as a square or the like. However, it can be understood that the round nail head 21 is most advantageous for industrialization.

For industrialization, the rivet 20 is assembled into the perforation 14 of the double-sided circuit board 10, the rivet 20 is generally sucked up and inserted into the perforation 14 through the patch machine and the suction nozzle of the patch machine. The patch machine is a prior art and is well known to those skilled in the art and will not be described herein. Therefore, the width of the shank 22 is smaller than the diameter of the perforation 14 in order to be compatible with the error of the patch machine within a certain range, that is, when the error of the patch machine is within the range of the difference between the width of the shank 20 and the diameter of the perforation 14, the shank 20 can be inserted into the perforation 14. The purpose of providing the transition portion 23 is to strengthen the connection strength between the nail head 21 and the shank 22, and at the same time, under the action of gravity and the unavoidable jitter of the double-sided circuit board 10 during the operation of the patch machine, Advantageously, the axis of the shank 22 coincides with the axis of the perforation 14, thereby facilitating the reliability of the electrical connection of the nail head 21 of the rivet 20 to the first wiring layout 12. Further, in order to smoothly insert the rivet 20 into the perforation 14, the free end of the shank 22 is tapered.

The LED chip 30 is a prior art, which is also placed on the first wiring layout 12 of the double-sided circuit board 10 together with the rivet 20 by a patch machine, and then the LED chip 30 is soldered to the first wiring layout 12 by reflow soldering.

The electronic component 40 is disposed on the other side of the circuit substrate 11 and electrically connected to the second wiring layout 13. It is conceivable that the electronic component 40 may include components such as resistors, capacitors, transistors, diodes, etc. for the purpose of decompression shunt, the structure and working principle thereof, and the connection method should be the technology in the art. As far as the personnel are concerned, they will not be explained in detail here.

As shown in FIG. 5, it is a flowchart of a method of manufacturing the LED light source module 100. The manufacturing method of the LED light source module 100 includes the following steps:

Step 101: Providing a double-sided circuit board 10 of the LED light source module 100 as described above;

Step 102: Providing a patch machine 50, as shown in FIG. 3, the patch machine 50 includes at least one nozzle mounting device 51, at least one suction nozzle 52 mounted on the nozzle mounting device 51, and a circuit board placing table 53. Referring to FIG. 4, the suction nozzle 52 includes a hollow cylinder 521, and a step portion 522 disposed on the free end of the hollow cylinder 521, on a section along the axis of the hollow cylinder 521, the length of the step portion 522 is equivalent to the length of the nail head 21;

Step 103:Providing electronic components 40, rivets 20, and LED chips 30 to be soldered to the double-sided circuit board 10, and solder paste used for soldering the electronic components, rivets, LED chips, and first and second wiring layouts 12, 13 (not shown in the figure);

Step 104: Placing the double-sided circuit board 10 on the circuit board placing table 53;

Step 105: The patch machine 50 is used to lay the solder paste on the side of the double-sided circuit board 10 on which the second wiring layout 13 is disposed and attach the electronic component 40;

Step 106: Performing reflow soldering to electrically connect the electronic component 40 to the second wiring layout 13;

Step 107:Laying a solder paste on the side of the double-sided circuit board 10 on which the first wiring layout 12 is disposed by the patch machine 50, and attaching the LED chip 30 while sucking the rivet 20 through the suction nozzle 52, and inserting the rivet 20 into the perforation 14;

Step 108:Performing reflow soldering to electrically connect the LED chip 30 to the first wiring layout 12, and electrically connecting and fixing the nail head 21 of the rivet 20 to the first wiring layout 12;

Step 109:Repair welding the shank 22 of the rivet 20 protruding from the side of the second wiring layout 13 to electrically connect the rivet 20 and the second wiring layout 13 to complete the assembly of the LED light source module 100.

In step 109, the repair welding may be done manually or by a machine.

In step 102, the height of the step portion 522 in the axial direction of the hollow cylinder 521 is equivalent to the height of the nail head 21. There are two main ways in which the patch machine 50 can travel, one is a parallel movement type, and the other is a circular movement type. Regardless of the type of travel, the suction nozzle 52 drives the sucked component to move, and the moving speed is faster, and from rest to movement, the sucked component is easily dropped under the action of inertia, especially when the rivet 20 has a small volume. In the present embodiment, the diameter of the nail head 21 of the rivet 20 is only 1.0 mm, and the diameter of the shank 22 is only 0.5 mm. Therefore, the step portion 522 is provided at the free end of the suction nozzle 52. When the nail head 21 is inset into the step portion 52, the nozzle mounting device 51 of the patch machine 50 can be prevented from dropping the rivet 20 during traveling, so that the reliability of processing can be ensured.

Compared with the prior art, the double-sided circuit board 10 of the LED light source module 100 of the present invention is electrically connected to the first and second wiring layouts 12 and 13 through the rivet 20, and does not use the heavily contaminated copper sink. The process can reduce the cost of pollution control, and at the same time, when assembling the rivet, the high temperature like the copper sink process is not required, so that the circuit substrate 11 of a lower-grade material, such as a composite substrate containing a paper base, can be used. Therefore, the cost can be reduced in terms of materials, and the overall cost of the LED light source module 100 can be reduced to improve the competitiveness of the lamp having the LED light source module 100.

The above disclosure has been described by way of example and in terms of exemplary embodiment, and it is to be understood that the disclosure is not limited thereto. Rather, any modifications, equivalent alternatives or improvement etc. within the spirit of the invention are encompassed within the scope of the invention as set forth in the appended claims.

1. An LED light source module, characterized in that: the LED light source module comprises a double-sided circuit board and at least one rivet electrically connected to two sides of the double-sided circuit board, the double-sided circuit board comprising a circuit substrate and at least one first wiring layout disposed on one side of the circuit substrate, and at least one second wiring layout disposed on the other side of the circuit board, and a perforation formed between the first wiring layout and the second wiring layout, the rivet being disposed in the perforation to electrically connect the first and second wiring layouts, the rivet including a nail head, a shank, and a transition section connecting the nail head and the shank, the length of the nail head in the cross section along the thickness direction of the circuit substrate is greater than the width of the shank, and the transition section is a trapezoid, the short side of the trapezoid is connected to the shank, the length of the long side of the trapezoid is smaller than the length of the nail head, the nail head is electrically connected to the first wiring layout, and the shank is electrically connected to the second wiring layout by soldering.

2. An LED light source module as claimed in claim 1, wherein the circuit substrate is made of a composite board which is composited from paper material and fiber material.

3. An LED light source module as claimed in claim 1, wherein the length of the shank is greater than the thickness of the circuit substrate.

4. An LED light source module as claimed in claim 1, wherein the width of the shank is smaller than the diameter of the perforation.

5. An LED light source module as claimed in claim 1, wherein the free end of the shank is tapered.

6. An LED light source module as claimed in claim 1, wherein the rivet is made of metal.

7. An LED light source module as claimed in claim 1, wherein the LED light source module further includes a plurality of LED chips electrically connected to one side of the double-sided circuit board, and a plurality of electronic components electrically connected to the other side of the double-sided circuit board, the LED chips is electrically connected to the first wiring layout, and the electronic component is electrically connected to the second wiring layout.

8. A LED light source module manufacturing method, which comprises the following steps:
providing a double-sided circuit board of the LED light source module as described in claims 1 to 7;
providing a patch machine, the patch machine including at least one nozzle mounting device, at least one suction nozzle mounted on the nozzle mounting device, and a circuit board placing table, the suction nozzle including a hollow cylinder, and a step portion disposed on the free end of the hollow cylinder, on a section along the axis of the hollow cylinder, the length of the step portion is equivalent to the length of the nail head;
providing electronic components, rivets, and LED chips to be soldered to the double-sided circuit board, and solder paste used for soldering the electronic components, rivets, LED chips, and first and second wiring layouts;
placing the double-sided circuit board on the circuit board placing table;
the patch machine is used to lay the solder paste on the side of the double-sided circuit board on which the second wiring layout is disposed and attach the electronic component;
performing reflow soldering to electrically connect the electronic component to the second wiring layout;
laying the solder paste on the side of the double-sided circuit board on which the first wiring layout is disposed by the patch machine, and attaching the LED chip while sucking the rivet through the suction nozzle, and inserting the rivet into the perforation;
performing reflow soldering to electrically connect the LED chip to the first wiring layout, and electrically connecting and fixing the nail head of the rivet to the first wiring layout;
repair welding the shank of the rivet protruding from the side of the second wiring layout to electrically connect the rivet and the second wiring layout to complete the assembly of the LED light source module.

9. A LED light source module manufacturing method as claimed in claim 8, wherein the repair welding is done by hand.

10. A LED light source module manufacturing method as claimed in claim 8, wherein the height of the step portion in the axial direction of the hollow cylinder is equal to the height of the nail head.
